(19) United States
(12) Patent Application Publication
(10) Pub. No.: US 2026/0246425 A1
(43) Pub. Date: Aug. 20, 2026

(54) LOW-FREQUENCY CURRENT MODULATION IN A POWER MANAGEMENT INTEGRATED CIRCUIT

(71) Applicant: Qorvo US, Inc., Greensboro, NC (US)

(72) Inventor: Nadim Khlat, Ceret (FR)

(21) Appl. No.: 19/162,535

(22) PCT Filed: Jan. 9, 2024
(86) PCT No.: PCT/US2024/010804

§ 371 Date: Sep. 5, 2025

Related U.S. Application Data
(60) Provisional application No. 63/489,026, filed on Mar. 8, 2023.

(51) Int. Cl. H03F 1/02; H03F 3/24

(52) U.S. Cl. CPC H03F 1/0227; H03F 3/245; H03F 2200/351; H03F 2200/375; H03F 2200/451

(57) ABSTRACT

Low-frequency current modulation in a power management integrated circuit (PMIC) is provided. The PMIC includes a voltage processing circuit and a switcher circuit. The voltage processing circuit can generate a voltage for amplifying a radio frequency (RF) signal. The switcher circuit can provide a low-frequency current to assist the voltage processing circuit in adapting the voltage swiftly. In embodiments disclosed herein, the switcher circuit can be configured to modulate the low-frequency current in accordance with a target of the voltage and when a modulation bandwidth of the RF signal is above a bandwidth threshold (e.g., 10 MHz). In contrast, when the modulation bandwidth is below the bandwidth threshold, the switcher circuit will not modulate the low-frequency current. By adapting the low-frequency current to the modulation bandwidth, the PMIC can operate more efficiently across an entire modulation bandwidth of the RF signal.

### RELATED APPLICATIONS

This application claims the benefit of U.S. provisional patent application Ser. No. 63/489,026, filed on Mar. 8, 2023, the disclosures of which is hereby incorporated herein by reference in its entirety.

### FIELD OF THE DISCLOSURE

The technology of the disclosure relates generally to a power management integrated circuit (PMIC).

### BACKGROUND

Fifth generation (5G) new radio (NR) (5G-NR) has been widely regarded as the next generation of wireless communication technology beyond the current third generation (3G) and fourth generation (4G) technologies. In this regard, a wireless communication device capable of supporting the 5G-NR wireless communication technology is expected to achieve higher data rates, improved coverage range, enhanced signaling efficiency, and reduced latency.

Downlink and uplink transmissions in a 5G-NR system are widely based on orthogonal frequency division multiplexing (OFDM) technology. In an OFDM based system, physical radio resources are divided into a number of subcarriers in a frequency domain and a number of OFDM symbols in a time domain. The subcarriers are orthogonally separated from each other by a subcarrier spacing (SOS). The OFDM symbols are separated from each other by a cyclic prefix (CP), which acts as a guard band to help overcome inter-symbol interference (ISI) between the OFDM symbols.

A radio frequency (RF) signal communicated in the OFDM based system is often modulated into multiple subcarriers in the frequency domain and multiple OFDM symbols in the time domain. The multiple subcarriers occupied by the RF signal collectively define a modulation bandwidth of the RF signal. The multiple OFDM symbols, on the other hand, define multiple time intervals during which the RF signal is communicated. In the 5G-NR system, the RF signal is typically modulated with a high modulation bandwidth in excess of 200 MHz.

The duration of an OFDM symbol depends on the SCS and the modulation bandwidth. The table below (Table 1) provides some OFDM symbol durations, as defined by 3G partnership project (3GPP) standards for various SCSs and modulation bandwidths. Notably, the higher the modulation bandwidth is, the shorter the OFDM symbol duration will be. For example, when the SCS is 120 KHz and the modulation bandwidth is 400 MHz, the OFDM symbol duration is 8.93 μs.

TABLE 1

| | | | | OFDM | |
|---|---|---|---|---|---|
| | Slot | # of Slots | | Symbol | Modulation |
| SCS | Length | per | CP | Duration | Bandwidth |
| (KHz) | (μs) | Subframe | (μs) | (μs) | (MHz) |
| 15 | 1000 | 1 | 4.69 | 71.43 | 50 |
| 30 | 500 | 2 | 2.34 | 35.71 | 100 |
| 60 | 250 | 4 | 1.17 | 17.86 | 200 |
| 120 | 125 | 8 | 0.59 | 8.93 | 400 |

In a 5G-NR system, the RF signal can be modulated with a time-variant power that changes from one OFDM symbol to another. In this regard, a power amplifier circuit(s) is required to amplify the RF signal to a certain power level within each OFDM symbol duration. Such inter-symbol power variation creates a unique challenge for a power management integrated circuit (PMIC) because the PMIC must be able to adapt a voltage supplied to the power amplifier circuit within the CP of each OFDM symbol to help avoid distortion (e.g., amplitude clipping) in the RF signal.

### SUMMARY

Embodiments of the disclosure relate to low-frequency current modulation in a power management integrated circuit (PMIC). The PMIC includes a voltage processing circuit and a switcher circuit. The voltage processing circuit can generate a voltage for amplifying a radio frequency (RF) signal. The switcher circuit can provide a low-frequency current to assist the voltage processing circuit in adapting the voltage swiftly. In embodiments disclosed herein, the switcher circuit can be configured to modulate the low-frequency current in accordance with a target of the voltage and when a modulation bandwidth of the RF signal is above a bandwidth threshold (e.g., 10 MHz). In contrast, when the modulation bandwidth is below the bandwidth threshold, the switcher circuit will not modulate the low-frequency current. By adapting the low-frequency current to the modulation bandwidth, the PMIC can operate more efficiently across an entire modulation bandwidth of the RF signal.

In one aspect, a PMIC is provided. The PMIC includes a switcher circuit. The switcher circuit is configured to generate a low-frequency current based on a duty cycle signal. The PMIC also includes a voltage processing circuit. The voltage processing circuit is configured to utilize the low-frequency current to generate a voltage at a voltage output for amplifying an RF signal. The PMIC also includes a control circuit. The control circuit is configured to generate the duty cycle signal to cause the switcher circuit to modulate the low-frequency current when a modulation bandwidth of the RF signal is above a bandwidth threshold.

In another aspect, a wireless device is provided. The wireless device includes a PMIC. The PMIC includes a switcher circuit. The switcher circuit is configured to generate a low-frequency current based on a duty cycle signal. The PMIC also includes a voltage processing circuit. The voltage processing circuit is configured to utilize the low-frequency current to generate a voltage at a voltage output for amplifying an RF signal. The PMIC also includes a control circuit. The control circuit is configured to generate the duty cycle signal to cause the switcher circuit to modulate the low-frequency current when a modulation bandwidth of the RF signal is above a bandwidth threshold.

In another aspect, a method for supporting low-frequency current modulation in a PMIC is provided. The method includes generating a low-frequency current based on a duty cycle signal. The method also includes utilizing the low-frequency current to generate a voltage at a voltage output for amplifying an RF signal. The method also includes generating the duty cycle signal to cause the low-frequency current to be modulated when a modulation bandwidth of the RF signal is above a bandwidth threshold.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an exemplary wireless communication circuit wherein a power management integrated circuit (PMIC) is configured according to embodiments of the present disclosure to adapt a low-frequency current to a modulation bandwidth of a radio frequency (RF) signal;

FIG. 2 is a schematic diagram of a control circuit in the PMIC in FIG. 1, which is configured according to embodiments of the present disclosure to cause the PMIC to adapt the low-frequency current to the modulation bandwidth of the RF signal;

FIG. 3 is a schematic diagram of an exemplary equivalent electrical model incorporating the PMIC in FIG. 1 and the control circuit in FIG. 2;

FIG. 4 is a schematic diagram of an exemplary user element wherein the wireless communication circuit of FIG. 1 can be provided; and

FIG. 5 is a flowchart of an exemplary process whereby the wireless communication circuit of FIG. 1 can support low-frequency current modulation.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to low-frequency current modulation in a power management integrated circuit (PMIC). The PMIC includes a voltage processing circuit and a switcher circuit. The voltage processing circuit can generate a voltage for amplifying a radio frequency (RF) signal. The switcher circuit can provide a low-frequency current to assist the voltage processing circuit in adapting the voltage swiftly. In embodiments disclosed herein, the switcher circuit can be configured to modulate the low-frequency current in accordance with a target of the voltage and when a modulation bandwidth of the RF signal is above a bandwidth threshold (e.g., 10 MHz). In contrast, when the modulation bandwidth is below the bandwidth threshold, the switcher circuit will not modulate the low-frequency current. By adapting the low-frequency current to the modulation bandwidth, the PMIC can operate more efficiently across an entire modulation bandwidth of the RF signal.

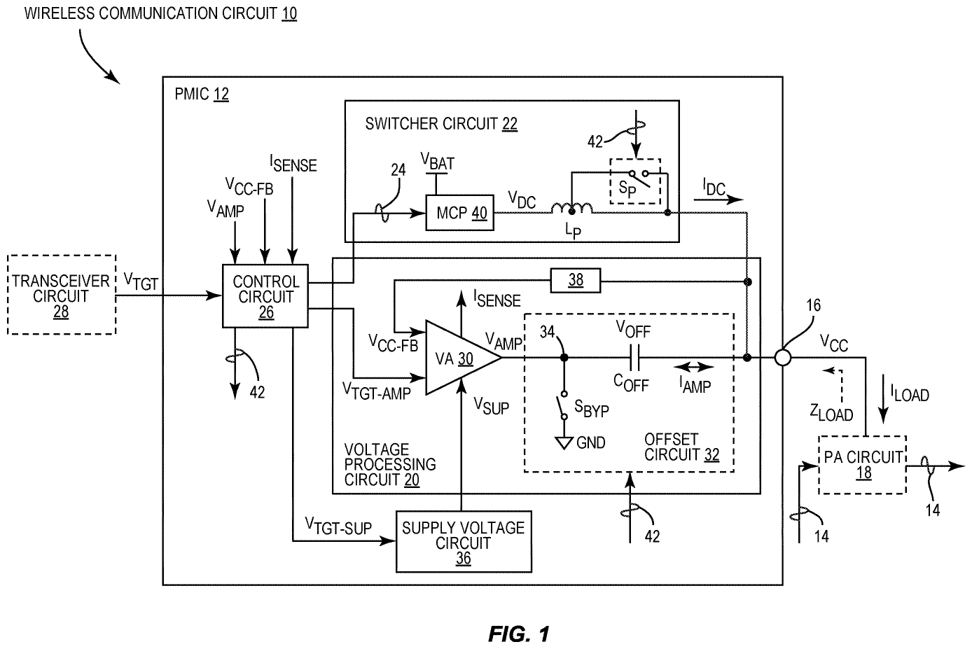

FIG. 1 is an exemplary wireless communication circuit 10 wherein a PMIC 12 is configured according to embodiments of the present disclosure to adapt a low-frequency current I_{DC} to a modulation bandwidth of an RF signal 14. The PMIC 12 includes a voltage output 16 that outputs a voltage V_{CC} to a power amplifier circuit 18 for amplifying the RF signal 14. The voltage V_{CC} received by the power amplifier circuit 18 can cause a load current ILOAD in the power amplifier circuit 18. Accordingly, the PMIC 12 will see a load impedance Z_{LOAD} at the voltage output 16.

The PMIC 12 includes a voltage processing circuit 20 that is coupled to the voltage output 16. The voltage processing circuit 20 is configured to generate the voltage V_{CC} at the voltage output 16. The PMIC 12 also includes a switcher circuit 22 that can generate the low-frequency current I_{DC} in accordance with a duty cycle signal 24. Herein, the low-frequency current I_{DC} plays an important role in assisting the voltage processing circuit 20 to adapt (increase or decrease) the voltage V_{CC} in a timely fashion, such as within a cyclic prefix (CP) of an orthogonal frequency division multiplexing (OFDM) symbol. As described below, the switcher circuit 22 can be configured to adapt the low-frequency current I_{DC} in accordance with a modulation bandwidth of the RF signal 14. More specifically, the switcher circuit 22 can be configured to generate the low-frequency current I_{DC} as a modulated current (e.g., time-variant current) when the modulation bandwidth of the RF signal 14 is above a bandwidth threshold (e.g., >10 MHz) or to generate the low-frequency current I_{DC} as a non-modulated current (e.g., constant current) when the modulation bandwidth of the RF signal 14 is below or equal to the bandwidth threshold (e.g., ≤10 MHz or ≤5 MHz). By adapting the low-frequency current I_{DC} to the modulation bandwidth of the RF signal 14, the PMIC 12 can thus operate more efficiently across an entire modulation bandwidth of the RF signal 14.

The PMIC 12 further includes a control circuit 26. In an embodiment, the control circuit 26 is configured to determine whether the modulation bandwidth of the RF signal 14 is above or below the bandwidth threshold. In a non-limiting example, the control circuit 26 can receive an indication of the modulation bandwidth of the RF signal 14 from a transceiver circuit 28, which also provides a target voltage V_{TGT} that indicates how the voltage V_{CC} should change, for example, from one OFDM symbol to another. The bandwidth threshold, on the other hand, may be preprogrammed in the control circuit 26 (e.g., in a memory or a register). Herein, the control circuit 26 is configured to generate the duty cycle signal 24 based on the modulation bandwidth of the RF signal 14 and the target voltage V_{TGT} to thereby cause the switcher circuit 22 to modulate or not to modulate the low-frequency current I_{DC}.

The voltage processing circuit 20 includes a voltage amplifier 30 (denoted as “VA”) and an offset circuit 32. The voltage amplifier 30 is coupled to an input 34 of the offset circuit 32 and the offset circuit 32 is coupled to the voltage output 16. In the context of the present disclosure, the power amplifier circuit 18 is assumed to have a much higher bandwidth than that of the offset circuit 32.

Specifically, the voltage amplifier 30 is configured to generate an initial voltage V_{AMP} based on (a.k.a. tracking) an amplifier target voltage V_{TGT-AMP}, which is proportionally related to the target voltage V_{TGT}, and a supply voltage V_{SUP}. A supply voltage circuit 36 is configured to generate the supply voltage V_{SUP} based on a supply target voltage V_{TGT-SUP} and provide the supply voltage V_{SUP} to the voltage amplifier 30.

The offset circuit 32 includes an offset capacitor C_{OFF} and a bypass switch S_{BYP}. The offset capacitor C_{OFF} is coupled between the input 34 and the voltage output 16, and the bypass switch S_{BYP} is coupled between the input 34 and a ground (GND). The offset capacitor C_{OFF} may be charged or discharged to provide an offset voltage V_{OFF} between the voltage amplifier 30 and the voltage output 16. As a result, the offset circuit 32 can raise the initial voltage V_{AMP} by the offset voltage V_{OFF} to thereby generate the voltage V_{CC} at the voltage output 16 (V_{CC}=V_{AMP}+V_{OFF}). The voltage processing circuit 20 further includes a feedback loop 38, which is configured to provide a feedback of the voltage V_{CC} (denoted as “V_{CC-FB}”) at the voltage output 16 to the voltage amplifier 30.

The switcher circuit 22 includes a multi-level charge pump (MCP) 40. The MCP 40, which may be a direct current (DC)-DC buck-boost converter, is configured to generate a low-frequency voltage V_{DC} (e.g., DC voltage) based on a battery voltage V_{BAT}. Specifically, the MCP 40 may operate in a buck mode to generate the low-frequency voltage V_{DC} at 0×V_{BAT} or 1×V_{BAT}, or in a boost mode to generate the low-frequency voltage V_{DC} at 2×V_{BAT}. The MCP 40 may be configured to toggle between the buck mode and the boost mode based on the duty cycle signal 24 (e.g., 20%@0×V_{BAT}, 30%@1×V_{BAT}, and 50%@2×V_{BAT}). Accordingly, the MCP 40 may be controlled by the duty cycle signal 24 to generate the low-frequency voltage V_{DC} at any desired level.

The switcher circuit 22 also includes a power inductor L_{P} coupled in series to the MCP 40. The power inductor L_{P} is configured to induce a low-frequency current I_{DC} based on the low-frequency voltage V_{DC}. Given that the duty cycle signal 24 can directly control the low-frequency voltage V_{DC}, the duty cycle signal 24 can likewise cause the low-frequency current I_{DC} to be generated at any desired amount. In a non-limiting example, the duty cycle signal 24 can be a sawtooth wave signal. As such, the duty cycle signal 24 can be so generated to cause the switcher circuit 22 to generate the low-frequency current I_{DC} with time-variant amplitude (a.k.a. modulated current) or non-time-variant amplitude (a.k.a. non-modulated current or constant current).

The power inductor L_{P} may be an adjustable power inductor. In an embodiment, the control circuit 26 may control an inductor switch SP via a control signal 42 to increase or decrease inductance of the adjustable power inductor L_{P}. As an example, when the modulation bandwidth of the RF signal 14 is above the bandwidth threshold, the control circuit 26 can configure the adjustable power inductor L_{P} to present a lower inductance to thereby modulate the low-frequency current I_{DC} in an increased bandwidth to help reduce content of a high-frequency current I_{AMP} versus frequency. In contrast, when the modulation bandwidth of the RF signal 14 is below or equal to the bandwidth threshold, the control circuit 26 may configure the adjustable power inductor L_{P} to present a higher inductance to thereby reduce the bandwidth of the switcher circuit 22.

As mentioned earlier, the voltage V_{CC} at the voltage output 16 is determined by the initial voltage V_{AMP} and the offset voltage V_{OFF}. In this regard, it is possible to change the voltage V_{CC} by increasing or decreasing the offset voltage V_{OFF}, either in addition to or alternative to changing the initial voltage V_{AMP}. Specifically, to increase the offset voltage V_{OFF}, the control circuit 26 may close the bypass switch S_{BYP} (e.g., via the control signal 42) such that the low-frequency current I_{DC} can charge the offset capacitor C_{OFF} to the offset voltage V_{OFF}. To decrease the offset voltage V_{OFF}, the control circuit 26 can lower the low-frequency voltage V_{DC} such that the offset capacitor C_{OFF} can be discharged through the power inductor L_{P} to decrease the offset voltage V_{OFF}.

In an embodiment, the voltage amplifier 30 may also source or sink the high-frequency current I_{AMP} (e.g., an alternating current) to help speed up charging or discharging of the offset capacitor C_{OFF}. Accordingly, the voltage amplifier 30 is configured to generate a sense current I_{SENSE} to indicate an amount of the high-frequency current I_{AMP} that is sourced or sunk by the voltage amplifier 30. Understandably, sourcing or sinking the high-frequency current I_{AMP} may reduce operating efficiency of the voltage amplifier 30 and increase energy waste in the PMIC 12. As such, it is desirable to minimize the high-frequency current I_{AMP} in the PMIC 12. As described below, the sense current I_{SENSE} can be utilized to determine the duty cycle signal 24 to help generate the low-frequency current I_{DC} not only in a desired amount but also in a desired mode of modulation.

In an embodiment, the control circuit 26 is configured to receive the feedback V_{CC-FB} of the voltage V_{CC}, the initial voltage V_{AMP}, and the sense current I_{SENSE}. Accordingly, the control circuit 26 can determine the amplifier target voltage V_{TGT-AMP}, the supply target voltage V_{TGT-SUP}, and the duty cycle signal 24 to thereby cause the switcher circuit 22 to adapt the low-frequency current I_{DC} in accordance with the modulation bandwidth of the RF signal 14.

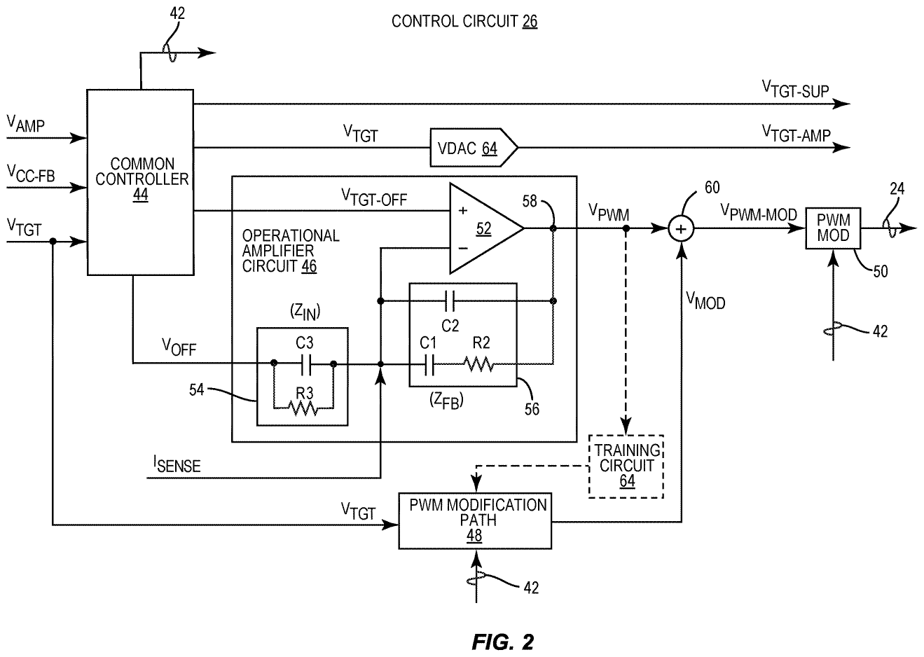

FIG. 2 is a schematic diagram providing an exemplary illustration of the control circuit 26 in the PMIC 12 in FIG. 1. Common elements between FIGS. 1 and 2 are shown therein with common element numbers and will not be re-described herein.

Herein, the control circuit 26 includes a common controller 44 (e.g., a microprocessor, a microcontroller, etc.), an operational amplifier circuit 46, a pulse-width modulation (PWM) modification path 48, and a PWM modulator 50. The common controller 44 is configured to receive the target voltage V_{TGT} from the transceiver circuit 28 in FIG. 1. In addition, the common controller 44 is also configured to receive the feedback V_{CC-FB} of the voltage V_{CC} and the initial voltage V_{AMP} at the input 34 of the offset circuit 32. Accordingly, the common controller 44 can determine a present value of the offset voltage V_{OFF} based on the received feedback V_{CC-FB} and the initial voltage V_{AMP}. The common controller 44 may also determine an offset target voltage V_{TGT-OFF} based on the target voltage V_{TGT}. As an example, the common controller 44 can store a lookup table (LUT) in an internal memory (not shown). The LUT may correlate different values of the target voltage V_{TGT} with different values of the offset target voltage V_{TGT-OFF}.

The operational amplifier circuit 46 includes an operational amplifier 52, an input circuit 54, and a feedback circuit 56. The operational amplifier 52 includes a non-inverted input terminal (denoted as “+”), an inverted input terminal (denoted as “−”), and an output terminal 58. The input circuit 54 is coupled between the common controller 44 and the inverted input terminal (“−”), the feedback circuit 56 is coupled between the inverted input terminal (“−”) and the output terminal 58. The output terminal 58 is coupled to the PWM modulator 50 via a combiner 60.

The common controller 44 is configured to provide the offset target voltage V_{TGT-OFF} directly to the non-inverted input terminal (“+”). The common controller 44 is also configured to provide the present value of the offset voltage V_{OFF} to the inverted input terminal (“−”) via the input circuit 54. The inverted input terminal (“−”) is further configured to receive the sense current I_{SENSE}, as generated by the voltage amplifier 30 in FIG. 1. Accordingly, the operational amplifier 52 can generate a PWM target voltage V_{PWM} at the output terminal 58 based on the offset target voltage V_{TGT-OFF}, the present value of the offset voltage V_{OFF}, and the sense current I_{SENSE}. Herein, the PWM target voltage V_{PWM} can be determined in accordance with equation (Eq. 1) below.

$${V}_{PWM} = {V}_{OFF} + {Z}_{FB} / {Z}_{IN} * ( {V}_{TGT - OFF} - {V}_{OFF} ) - {Z}_{FB} * {I}_{SENSE} \qquad ( Eq . 1 )$$

In the equation (Eq. 1) above, ZIN represents an impedance of the input circuit 54 and Z_{FB} represents an impedance of the feedback circuit 56. In an embodiment, in response to determining that the modulation bandwidth of the RF signal 14 is above the bandwidth threshold, the common controller 44 may activate the PWM modification path 48 (e.g., via the control signal 42). In contrast, in response to determining that the modulation bandwidth of the RF signal 14 is below or equal to the bandwidth threshold, the common controller 44 may deactivate the PWM modification path 48.

In a non-limiting example, the PWM modification path 48 can include a coupling switch (not shown). Accordingly, the common controller 44 may close the coupling switch to couple the PWM modification path 48 to the combiner 60 or open the coupling switch to decouple the PWM modification path 48 from the combiner 60. In this regard, the common controller 44 may activate or deactivate the PWM modification path 48 by closing or opening the coupling switch.

When activated, the PWM modification path 48 will generate a PWM modification voltage V_{MOD} based on the target voltage V_{TGT} and provide the PWM modification voltage V_{MOD} to the combiner 60. The combiner 60, in turn, combines the PWM target voltage V_{PWM} with the PWM modification voltage V_{MOD} to thereby generate a modified PWM target voltage V_{PWM-MOD} (V_{PWM-MOD}=V_{PWM}±V_{MOD}). Accordingly, the PWM modulator 50 will generate the duty cycle signal 24 based on a sum of the PWM target voltage V_{PWM} and the PWM modification voltage V_{MOD}.

In contrast, when the PWM modification path 48 is deactivated, the combiner 60 will not receive the PWM modification voltage V_{MOD}. As a result, the modified PWM target voltage V_{PWM-MOD} includes only the PWM target voltage V_{PWM}. Accordingly, the PWM modulator 50 will generate the duty cycle signal 24 based exclusively on the PWM target voltage V_{PWM}.

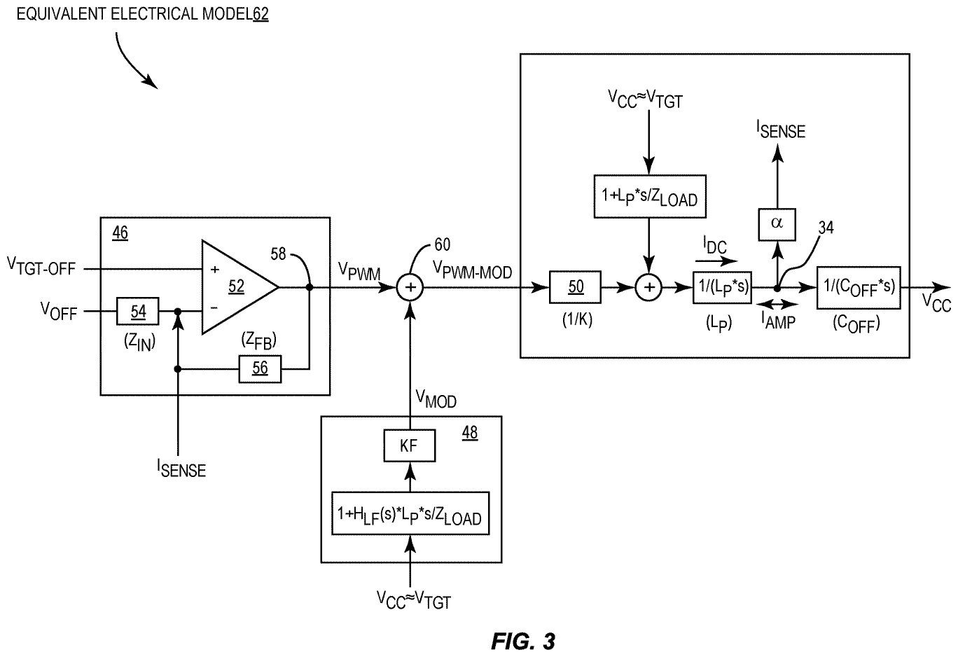

The operational principles of the PWM modification path 48 can be further explained based on an equivalent electrical model of the PMIC 12. In this regard, FIG. 3 is a schematic diagram of an exemplary equivalent electrical model 62 incorporating the PMIC 12 in FIG. 1 and the control circuit 26 in FIG. 2. Common elements between FIGS. 1, 2, and 3 are shown therein with common element numbers and will not be re-described herein.

Herein, the PWM modification path 48 is configured to apply a predefined transfer function, expressed as 1+H_{LF}(s)*L_{P}*S/Z_{LOAD}, in conjunction with a forward coefficient KF to the target voltage V_{TGT} to thereby generate the PWM modification voltage V_{MOD}, which can be expressed in equation (Eq. 2) below.

$${V}_{MOD} = KF * {V}_{TGT} * ( 1 + {H}_{LF} ( s ) * {L}_{P} * s / {Z}_{LOAD} ) \qquad ( Eq . 2 )$$

By adding the PWM modification voltage V_{MOD} to the PWM target voltage V_{PWM}, the low-frequency current I_{DC} as induced by the adjustable power inductor L_{P} will be modulated as V_{CC}*H_{LF}(S)/Z_{LOAD}. Accordingly, the high-frequency current I_{AMP}, as sourced or sunk by the voltage amplifier 30 in FIG. 1, can be expressed as in equation (Eq. 3) below.

$${I}_{AMP} = \frac{{V}_{TGT - OFF} * \frac{1 + \frac{{Z}_{FB}}{{Z}_{in}}}{K} + {V}_{TGT} * {( \frac{KF}{K} * ( 1 + \frac{{L}_{P} * {H}_{LF} ( s ) * s}{{Z}_{LOAD}} ) )}_{}}{{L}_{P} * s + \frac{{Z}_{FB}}{{Z}_{in}} * \frac{1}{K} * \frac{1}{{C}_{OFF} * {s}_{}} + {Z}_{FB} * \frac{α}{K}} \qquad ( Eq . 3 )$$

In the equation (Eq. 3), 1/K represents a gain of the PWM modulator 50 and α (α≤1) represents a scaling factor between the high-frequency current I_{AMP} and the sense current I_{SENSE} (i.e., I_{SENSE}=α*I_{AMP}). In contrast, when the PWM modification path is disabled (e.g., KF=0), the PWM modification voltage V_{MOD} will not be added to the PWM target voltage V_{PWM}. Accordingly, the high-frequency current I_{AMP} will be defined by equation (Eq. 4) below.

$${I}_{AMP} = \frac{\frac{{V}_{TGT - OFF}}{K} * ( 1 + \frac{{Z}_{FB}}{{Z}_{in}} ) - {V}_{TGT} * {( 1 + \frac{{L}_{P}}{{Z}_{LOAD}} * s )}_{}}{{L}_{P} * s + \frac{{Z}_{FB}}{{Z}_{in}} * \frac{1}{K} * \frac{1}{{C}_{OFF} * {s}_{}} + {Z}_{FB} * \frac{α}{K}} \qquad ( Eq . 4 )$$

By comparing equations (Eq. 3 and 4), it can be seen that adding the PWM modification voltage V_{MOD} to the PWM target voltage V_{PWM} can eliminate the term

$$“ {V}_{TGT} * ( 1 + \frac{{L}_{P}}{{Z}_{LOAD}} * s ) ”$$

from the high-frequency current I_{AMP}. In other words, the high-frequency current I_{AMP} is no longer dependent on the target voltage V_{TGT}. As a result, it is possible to minimize changes in the high-frequency current I_{AMP} when the PMIC 12 adapts the voltage V_{CC} based on the target voltage V_{TGT}.

With reference back to FIG. 2, the control circuit 26 may include a training circuit 64 (denoted as VDAC). In an embodiment, the training circuit 64 may be configured to adjust parameters associated with the transfer function 1+L_{P}/Z_{LOAD}*H_{LF}(s)*s based on feedback of the initial voltage V_{AMP}.

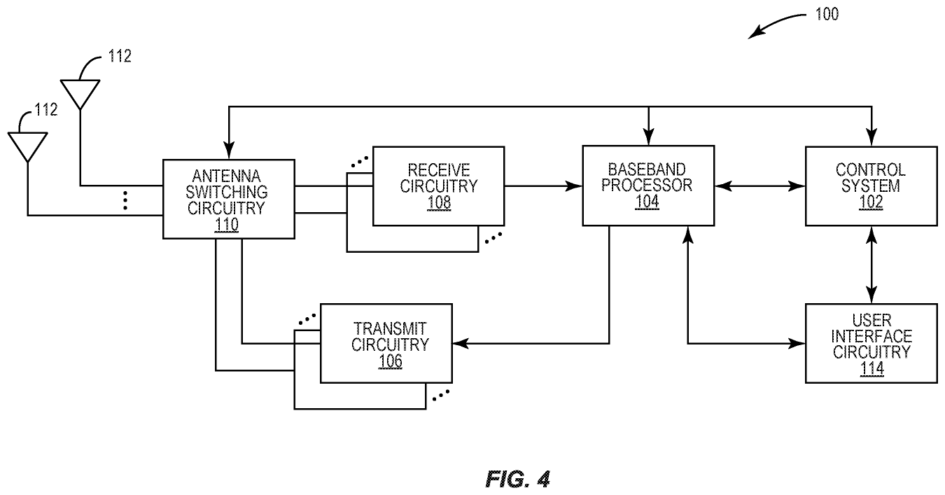

The wireless communication circuit 10 of FIG. 1 can be provided in a user element (e.g., a wireless device) to support low-frequency current modulation according to embodiments described above. In this regard, FIG. 4 is a schematic diagram of an exemplary user element 100 wherein the wireless communication circuit 10 of FIG. 1 can be provided.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

In an embodiment, the wireless communication circuit 10 of FIG. 1 can be provided in the transmit circuitry 106. In another embodiment, the transceiver circuit 28 in FIG. 1 can be part of the baseband processor 104, and the PMIC 12 and the power amplifier circuit 18 can be integrated with the transmit circuitry 106.

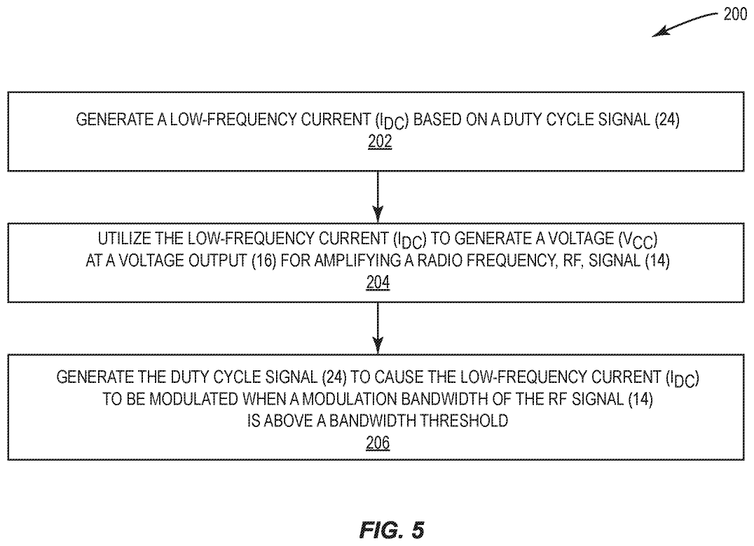

In an embodiment, the PMIC 12 in the wireless communication circuit 10 of FIG. 1 can be configured to support low-frequency current modulation in accordance with a process. In this regard, FIG. 5 is a flowchart of an exemplary process 200 whereby the PMIC 12 in the wireless communication circuit 10 of FIG. 1 can support low-frequency current modulation.

Herein, the process 200 includes generating the low-frequency current I_{DC} based on the duty cycle signal 24 (step 202). The process 200 also includes utilizing the low-frequency current I_{DC} to generate the voltage V_{CC} at the voltage output 16 for amplifying the RF signal 14 (step 204). The process 200 also includes generating the duty cycle signal 24 to cause the low-frequency current I_{DC} to be modulated when the modulation bandwidth of the RF signal 14 is above the bandwidth threshold (step 206).

Those skilled in the art will recognize improvements and modifications to the preferred embodiments of the present disclosure. All such improvements and modifications are considered within the scope of the concepts disclosed herein and the claims that follow.

1. A power management integrated circuit (PMIC) comprising:
a switcher circuit configured to generate a low-frequency current based on a duty cycle signal;
a voltage processing circuit configured to utilize the low-frequency current to generate a voltage at a voltage output for amplifying a radio frequency (RF) signal; and
a control circuit configured to generate the duty cycle signal to cause the switcher circuit to modulate the low-frequency current when a modulation bandwidth of the RF signal is above a bandwidth threshold.

2. The PMIC of claim 1, wherein the control circuit is further configured to generate the duty cycle signal to cause the switcher circuit to generate the low-frequency current as a constant current when the modulation bandwidth of the RF signal is below or equal to the bandwidth threshold.

3. The PMIC of claim 1, wherein the switcher circuit comprises:
a multi-level charge pump (MCP) configured to generate a low-frequency voltage as a function of a battery voltage based on the duty cycle signal; and
an adjustable power inductor configured to induce the low-frequency current based on the low-frequency voltage.

4. The PMIC of claim 3, wherein the control circuit is further configured to:
configure the adjustable power inductor to present a lower inductance when the modulation bandwidth is above the bandwidth threshold; and
configure the adjustable power inductor to present a higher inductance when the modulation bandwidth is below or equal to the bandwidth threshold.

5. The PMIC of claim 1, wherein the voltage processing circuit comprises:
a voltage amplifier configured to generate an initial voltage based on a target voltage and a supply voltage; and
an offset circuit coupled between the voltage amplifier and the voltage output and configured to utilize the low-frequency current to generate an offset voltage to thereby raise the initial voltage to the voltage at the voltage output.

6. The PMIC of claim 5, wherein the voltage amplifier is further configured to generate a sense current that is proportionally related to a high-frequency current flowing between the voltage amplifier and the offset circuit.

7. The PMIC of claim 6, wherein the control circuit comprises:
an operational amplifier circuit configured to generate a pulse-width modulation (PWM) target voltage based at least on the sense current;
a PWM modification path configured to generate a PWM modification voltage when the modulation bandwidth is above the bandwidth threshold; and
a PWM modulator configured to generate the duty cycle signal based on a sum of the PWM target voltage and the PWM modification voltage.

8. The PMIC of claim 7, wherein:
the PWM modification path is further configured not to generate the PWM modification voltage when the modulation bandwidth is below or equal to the bandwidth threshold; and
the PWM modulator is further configured to generate the duty cycle signal based on the PWM target voltage.

9. The PMIC of claim 7, wherein the PWM modification path is further configured to apply a predefined transfer function to the target voltage to thereby generate the PWM modification voltage.

10. The PMIC of claim 9, wherein the control circuit further comprises a training circuit configured to adjust parameters associated with the transfer function based on feedback of the initial voltage.

11. A wireless device comprising:
a power management integrated circuit (PMIC) comprising:
a switcher circuit configured to generate a low-frequency current based on a duty cycle signal;
a voltage processing circuit configured to utilize the low-frequency current to generate a voltage at a voltage output for amplifying a radio frequency (RF) signal; and
a control circuit configured to generate the duty cycle signal to cause the switcher circuit to modulate the low-frequency current when a modulation bandwidth of the RF signal is above a bandwidth threshold.

12. The wireless device of claim 11, wherein the control circuit is further configured to generate the duty cycle signal to cause the switcher circuit to generate the low-frequency current as a constant current when the modulation bandwidth of the RF signal is below or equal to the bandwidth threshold.

13. The wireless device of claim 11, wherein the switcher circuit comprises:
a multi-level charge pump (MCP) configured to generate a low-frequency voltage as a function of a battery voltage based on the duty cycle signal; and
an adjustable power inductor configured to induce the low-frequency current based on the low-frequency voltage.

14. The wireless device of claim 13, wherein the control circuit is further configured to:
configure the adjustable power inductor to present a lower inductance when the modulation bandwidth is above the bandwidth threshold; and
configure the adjustable power inductor to present a higher inductance when the modulation bandwidth is below or equal to the bandwidth threshold.

15. The wireless device of claim 11, wherein the voltage processing circuit comprises:
a voltage amplifier configured to generate an initial voltage based on a target voltage and a supply voltage; and
an offset circuit coupled between the voltage amplifier and the voltage output and configured to utilize the low-frequency current to generate an offset voltage to thereby raise the initial voltage to the voltage at the voltage output.

16. The wireless device of claim 15, wherein the voltage amplifier is further configured to generate a sense current that is proportionally related to a high-frequency current flowing between the voltage amplifier and the offset circuit.

17. The wireless device of claim 16, wherein the control circuit comprises:
an operational amplifier circuit configured to generate a pulse-width modulation (PWM) target voltage based at least on the sense current;
a PWM modification path configured to generate a PWM modification voltage when the modulation bandwidth is above the bandwidth threshold; and
a PWM modulator configured to generate the duty cycle signal based on a sum of the PWM target voltage and the PWM modification voltage.

18. The wireless device of claim 17, wherein:
the PWM modification path is further configured not to generate the PWM modification voltage when the modulation bandwidth is below or equal to the bandwidth threshold; and
the PWM modulator is further configured to generate the duty cycle signal based on the PWM target voltage.

19. The wireless device of claim 17, wherein the PWM modification path is further configured to apply a predefined transfer function to the target voltage to thereby generate the PWM modification voltage.

20. A method for supporting low-frequency current modulation in a power management integrated circuit (PMIC) comprising:
generating a low-frequency current based on a duty cycle signal;
utilizing the low-frequency current to generate a voltage at a voltage output for amplifying a radio frequency (RF) signal; and
generating the duty cycle signal to cause the low-frequency current to be modulated when a modulation bandwidth of the RF signal is above a bandwidth threshold.
